(19) United States
(12) Patent Application Publication
(10) Pub. No.: US 2018/0242452 A1
(43) Pub. Date: Aug. 23, 2018

(54) ELECTRICALLY CONDUCTIVE MATERIALS COMPRISING GRAPHENE

(71) Applicant: The University of Manchester, Manchester (GB)

(72) Inventors: Stephen YEATES, Manchester (GB); Mohammad Nazmul KARIM, Manchester (GB)

(21) Appl. No.: 15/751,781

(22) PCT Filed: Aug. 10, 2015
(86) PCT No.: PCT/GB2015/052309

§ 371 Date: Feb. 9, 2018

(51) Int. Cl. H05K 1/09; H05K 3/12; C09D 11/52; C09D 11/322; C09D 11/108; D06P 5/30; D06P 1/673; D06P 1/44; D06M 11/74; D06M 11/83; D06M 15/233; D06M 15/263; D06M 23/16

(52) U.S. Cl. CPC H05K 1/097; H05K 1/0386; H05K 3/1283; H05K 3/125; C09D 11/52; C09D 11/322; C09D 11/108; D06P 5/30; D06P 1/673; D06P 1/445; D06M 11/74; D06M 11/83; D06M 15/233; D06M 15/263; D06M 23/16; H05K 2201/0323; H05K 3/1208

(57) ABSTRACT

The present invention relates to electrically conductive materials. The present invention also relates to processes for the preparation of these materials and to electronic circuits, electronic devices and textile garments that comprise them.

### INTRODUCTION

The present invention relates to electrically conductive materials. The present invention also relates to processes for the preparation of these materials and to electronic circuits, electronic devices and textile garments that comprise them.

### BACKGROUND OF THE INVENTION

Flexible electronics have proved to be of considerable worth over the past few decades, and continue to find a diverse range of applications in numerous different fields, including health diagnostics [1], energy storage [2], food security [3], touch screens [4], electronic paper [5], sensors [6], radio frequency tags [7], light-emitting diodes [8] and electronic textiles [9].

The development of electronic textiles (e-textiles), in particular, has the potential to offer a wide spectrum of new products, ranging from fabric sensors, capable of detecting a host of different stimuli (e.g. temperature, electrocardiograms and movement), to fabric power generators, capable of harvesting the kinetic energy of the wearer and converting it into storable energy.

However, the development and subsequent utilization of e-textiles in wearable ‘smart’ garments has failed to find widespread use, mainly due to expensive production processes.

To date, the majority of e-textiles are produced by complex weaving processes and/or comprise the application of expensive metallic (often silver) based inks. This not only renders e-textiles expensive to produce but can often result in the end garment having reduced flexibility, a property which can ultimately cause discomfort to the wearer.

Accordingly, there remains a need for new, cost effective and efficient ways of producing flexible electronic materials, such as e-textiles.

The present invention was devised with the foregoing in mind.

### SUMMARY OF THE INVENTION

According to a first aspect of the present invention, there is provided an electrically conductive material comprising:

a porous substrate material;

a hydrophobic surface coating covering at least a portion of a surface of the porous substrate material; and

an electrically conductive track or film disposed on the hydrophobic surface coating; wherein:
(i) the hydrophobic surface coating forms a hydrophobic surface on the porous substrate material having an equilibrium contact angle of water against air, at 25° C., of greater than or equal to 60° and less than or equal to 175°; and
(ii) the electrically conductive track or film comprises graphene and/or reduced graphene oxide.

The contact angles quoted herein are the contact angles of the substrate surface 10 seconds after the hydrophobic coating has been applied.

According to a further aspect of the present invention, there is provided a process for forming an electrically conductive material, the process comprising:
(i) providing a porous substrate material;
(ii) digitally printing (e.g. inkjet printing) a hydrophobic surface coating formulation onto at least a portion of a surface of the porous substrate material to form a hydrophobic surface on the substrate having an equilibrium contact angle of water against air, at 25° C., of greater than or equal to 60° and less than or equal to 175°; and
(iii) digitally printing (e.g. inkjet printing) an electrically conductive formulation comprising graphene and/or graphene oxide onto the hydrophobic surface of the substrate to form a film or track; and thereafter reducing any graphene oxide present to form a track or film comprising reduced graphene oxide.

In a further aspect, the present invention provides an electrically conductive material obtainable by, obtained by, or directly obtained by any process of the present invention define herein.

According to a further aspect of the present invention, there is provided an electronic circuit or device comprising an electrically conductive material of the present invention.

According to a further aspect of the present invention, there is provided a textile or garment comprising an electrically conductive material of the present invention.

### DETAILED DESCRIPTION OF THE INVENTION

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

Unless otherwise specified, where the quantity or concentration of a particular component of a given composition or formulation is specified as a weight or volume percentage (wt. %, % w/w or % v/v), the percentage refers to the percentage of the stated component relative to the total weight or volume of the composition or formulation as a whole. It will be understood by those skilled in the art that the sum of weight or volume percentages of all components of a composition or formulation will total 100%. However, where not all components are listed (e.g. where formulations are said to “comprise” one or more particular components), the weight percentage balance may optionally be made up to 100% by unspecified components.

### Electronically Conductive Materials of the Present Invention

The present invention provides an electrically conductive material comprising:

a porous substrate material;

a hydrophobic surface coating covering at least a portion of a surface of the porous substrate material; and

an electrically conductive track or film disposed on the hydrophobic surface coating; wherein:
(i) the hydrophobic surface coating forms a hydrophobic surface on the porous substrate material having a an equilibrium contact angle of water against air, at 25° C., of greater than or equal to 60° and less than or equal to 175°; and
(ii) the electrically conductive track or film comprises pristine graphene and/or reduced graphene oxide.

The present invention also provides an electronically conductive material obtainable by, obtained by, or directly obtained by any of the fabrication processes of the present invention defined herein.

The electronically conductive materials of the present invention advantageously demonstrate suitably high conductivity and low resistivity, in addition to being cost effective and simple to produce.

In embodiments where the porous substrate material is a textile, it will be appreciated that the electronically conductive materials of the present invention make viable alternatives to current electronic textile materials.

### Porous Substrate Material

The electrically conductive materials of the present invention are formed on a porous substrate material. The term ‘porous substrate material’ will be understood by a person skilled in the art to mean a material having small holes that allow air or liquid, such as water, to pass, penetrate or absorb through.

The porous substrate material may be a textile or cellulosic material (e.g. paper). Suitably, the porous substrate material is a textile. Non-limiting examples of suitable textiles include cotton, nylon, polyester and combinations thereof.

It will be appreciated that the porous substrate will, in many embodiments, be flexible.

### Hydrophobic Surface Coating

The term ‘hydrophobic surface coating’ will be understood to mean a coating which imparts hydrophobicity to the surface of the substrate.

The hydrophobic surface that is formed on the substrate by the application of the hydrophobic surface coating is a surface that has an equilibrium contact angle of water against air, at 25° C., of greater than 60° and less than or equal to 175°.

The hydrophobic surface coating may include hydrophobic materials as well as superhydrophobic materials (i.e. materials that provide a hydrophobic surface having an equilibrium contact angle of greater than)150°.

The hydrophobic surface coating may comprise any suitable hydrophobic material or a mixture of such materials. Suitably, the hydrophobic material is a hydrophobic polymer.

In an embodiment, the hydrophobic surface coating comprises particles (e.g. microparticles) formed from a hydrophobic polymeric material.

In another embodiment, the hydrophobic surface coating comprises a curable material that can be cured in order to harden the hydrophobic surface coating. Suitable curable materials are well known in the art. In a particular embodiment, the curable material is a UV-curable material (or lacquer). It will be understood that curing such UV curable materials may then be cured by exposure to UV radiation following application to the substrate surface.

Any suitable hydrophobic polymer, or oligomer in the case of a UV curable material, may be used. Examples of suitable hydrophobic polymers include styrene, (meth)acrylate, acrylate, ester, olefin, vinyl ester, vinyl pyrrolidone, vinylpyridine based polymers and any appropriate copolymers. The skilled person will appreciate copolymers suitable for use. The suitable hydrophobic polymer may be cross-linked through suitable covalent or non-covalent interactions, typically triggered by heat or actinic radiation.

In an embodiment, the hydrophobic polymeric material is a polystyrene based polymer. In a specific embodiment, the hydrophobic polymeric material is a polystyrene based co-polymer comprising styrene, divinylbenzene and hydroxyl methacrylate.

In an embodiment, the hydrophobic surface coating forms a hydrophobic surface on the porous substrate material having an equilibrium contact angle of water against air, at 25° C., of greater than or equal to 90° and less than or equal to 175°. In a further embodiment, the hydrophobic coating forms a hydrophobic surface on the porous substrate material having an equilibrium contact angle of water against air, at 25° C., of greater than or equal to 90° and less than or equal to 165° . In a further embodiment, the hydrophobic coating forms a hydrophobic surface on the porous substrate material having an equilibrium contact angle of water against air, at 25° C., of greater than or equal to 90° and less than or equal to 145°. In a further embodiment, the hydrophobic coating forms a hydrophobic surface on the porous substrate material having an equilibrium contact angle of water against air, at 25° C., of greater than or equal to 90° and less than or equal to 135°. In a further embodiment, the hydrophobic coating forms a hydrophobic surface on the porous substrate material having an equilibrium contact angle of water against air, at 25° C., of greater than or equal to 100° and less than or equal to 125°.

It will be understood by a person skilled in the art that at time points close to zero seconds, both hydrophobic and hydrophilic droplets applied to a surface of a porous substrate material, such as a textile, can have measurable contact angles. However, a hydrophilic droplet will, over a short time, absorb into the porous substrate (e.g. textile) material, by virtue of its hydrophilicity, diminishing any measurable contact angle. For the avoidance of doubt, the inventors found that measuring the contact angle after a suitable period of time (e.g. 10 seconds) excludes such hydrophilic materials. Thus, the contact angles quoted herein are the contact angles after a time period of 10 seconds following the application of the hydrophobic surface coating material to a surface of the substrate.

It will be understood by a person skilled in the art that the number of layers (coatings) of the hydrophobic surface coating covering at least a portion of a surface of the porous substrate material may vary according to desired use of the electrically conductive material, and/or the type of porous substrate material used. Suitably, the number of layers (coatings) of hydrophobic surface coating on a surface of the porous substrate material is between 1 and 50 layers. More suitably, the number of layers of the hydrophobic surface coating is between 1 and 25 layers, and even more suitably between 1 and 20 layers and most suitably between 1 and 15 layers.

### Electrically Conductive Track or Film

In an embodiment, the electrically conductive track or film of the present invention comprises:
(i) pristine graphene;
(ii) reduced graphene oxide; or
(iii) pristine graphene and/or reduced graphene oxide in combination with one or more additional conductive agents.

Graphene is the name given to a particular crystalline allotrope of carbon in which each carbon atom is bound to three adjacent carbon atoms (in a sp² hybridised manner) so as to define a one atom thick planar sheet of carbon. The carbon atoms in graphene are arranged in the planar sheet in a honeycomb-like network of tessellated hexagons. Graphene is often referred to as a 2-dimensional crystal because it represents a single nanosheet or layer of carbon of nominal (one atom) thickness. Graphene is a single sheet of graphite. The term pristine graphene refers to ultrapure graphene, whereby little or no impurities or oxides are present. Pristine graphene displays little or very limited solubility in most organic solvents.

For the avoidance of doubt, the term graphene used herein does not encompass graphene oxide. Graphene oxide is an analogue form of graphene whereby oxygenated functionalities are introduced into the graphene structure. One advantage of graphene oxide over pristine graphene is its increased solubility, particularly in water. The reduction of the oxygenated functionality in graphene oxide consequently can lead to the generation of reduced graphene oxide, which is a form of graphene that still retains some residual oxygen content.

In the present invention, the electrically conductive track may comprise single layers of graphene or thin stacks of two to ten graphene layers. The thin stacks of graphene are distinguished from graphite by their thinness and a difference in physical properties. In this regard, it is generally acknowledged that crystals of graphene which have more than 10 molecular layers (i.e. 10 atomic layers which equates to a thickness of approximately 3.5 nm) generally exhibit properties more similar to graphite than to graphene. Thus, throughout this specification, the term graphene is intended to mean a carbon nanostructure with up to ten graphene layers.

Similarly, the reduced graphene oxide may be present as single layers of reduced graphene oxide or thin stacks of two to ten reduced graphene oxide layers.

In an embodiment, the electrically conductive track or film is formed from flakes of graphene or reduced graphene oxide that comprise 1 to 10 layers. Each layer of graphene or reduced graphene oxide present within a flake has a length and a width dimension to define the size of the plane of the layer. Typically, the length and width of the layers are within the range of 10 nm to 2 microns.

The flakes are deposited by digitally printing (e.g. inkjet printing) an electrically conductive ink formulation that compirses flakes of graphene or graphene oxide.

In the case of graphene oxide, the printed film or track will need to be reduced so as to form reduced graphene oxide that has superior electrical conductivity.

In certain embodiments, there may be additional electrically conductive agents present in the electrically conductive track or film, such as metallic components (e.g. silver precursor, silver nanoparticles, carbon nanotubes, or poly(3,4-ethylenedioxythiophene) polystyrene sulfonate (PEDOT/PSS)).

### Processes for Forming the Electrically Conductive Material

The present invention further provides a process for forming an electrically conductive material as defined herein.

The inventors have advantageously found that digital printing, in particular, inkjet printing, may be used as a simple and efficient way of producing the electrically conductive materials of the present invention. However, other digital deposition means may be envisaged such as, for example, jetronica technology developed by Alchemie Technology.

The use of digitally printing has a number of advantages over conventional fabrication processes. In particular, digitally printed conductive patterns are typically: faster to produce than subtractive processes (such as etching) or complex weaving processess; less wasteful; less hazardous (i.e. use less hazardous chemicals); less expensive than conventional techniques; compatible with a wide range of substrates; simple to implement; and enable the possibility of further post-fabrication processing.

Computer-controlled printer technology also allows for high-resolution digital printing, with the ability to place droplets of ink onto a substrate surface in response to a digital signal. Typically, the ink is transferred or jetted onto the surface without physical contact between the printing device and the surface. Within this general technique, the specific method by which the inkjet ink is deposited onto the substrate surface varies from system to system, and includes, amongst others, continuous ink deposition and drop-on-demand ink deposition. Ink droplets are ejected by the print head nozzle and are directed to the substrate surface.

The process for forming an electrically conductive material as defined herein, comprises:
(i) providing a porous substrate material;
(ii) digitally printing (e.g. inkjet printing) a hydrophobic coating formulation onto at least a portion of a surface of the porous substrate material to form a hydrophobic surface on the substrate having an equilibrium contact angle of water against air, at 25° C., of greater than or equal to 60° and less than or equal to 175°;
(iii) digitally printing (e.g. inkjet printing) an electrically conductive formulation comprising pristine graphene and/or graphene oxide onto the hydrophobic surface of the substrate to form a film or track and thereafter reducing any graphene oxide present to form a track or film comprising reduced graphene oxide; and
(iv) optionally, and if necessary, heating the printed electronically conductive formulation to between 50° C. and 300° C., so as to dry and/or cure the electronically conductive formulation.

Suitably, the electronically conductive formulation of the present invention is heated after digitally printing so as to cure the formulation. Suitably, the printed electronically conductive formulation is heated to a temperature of between 50° C. and 300° C. More suitably, the printed electronically conductive formulation is heated to a temperature of between 50° C. and 200° C. Even more suitably, the printed electronically conductive formulation is heated to a temperature of between 80° C. and 200° C. Most suitably, the printed electronically conductive formulation is heated to a temperature of between 100° C. and 150° C.

In an embodiment, the electronically conductive formulation of the present invention is heated photonically or by plasma treating.

In order to enhance the durability of the hydrophobic surface coating applied to the porous substrate material (prior to step (ii) in the process defined above), the surface of the porous substrate material may be pre-treated prior to the application of the hydrophobic surface coating. The treatment may involve the application of a suitable surface modifier agent. Without wishing to be bound by theory, it is understood that certain surface modifier agents aid the formation of permanent covalent bonds between functional groups (e.g. hydroxyl groups) on the surface of the porous substrate material and functional groups (e.g. hydroxyl groups) of the hydrophobic surface coating.

Any suitable surface modifier capable of enhancing covalent interactions between the porous substrate material and the hydrophobic surface coating may be used in the electrically conductive materials of the present invention. In an embodiment, the surface modifier is an aldehyde-based material, a carbonimide or a block isocyante. Suitably, the surface modifier is an aldehyde-based material, for example, a formaldehyde-based material such as urea formaldehyde or melamine formaldehyde. In an embodiment, the surface modifier is melamine formaldehyde.

The surface modifier is suitably applied in the form of a solution in a suitable solvent, such as, an organic solvent.

In an embodiment, the surface modifier is a solution of 20 to 70% w/v (e.g. 50% w/v) melamine formaldehyde in methanol.

Additional agents, such as, for example, organic acids including, but not limited to, para-toluene sulfonic acid, acetic acid, formic acid, citric acid, lactic acid, methanesulfonic acid and trifluoracetic acid, may also be used for the pre-treatment of the substrate surface.

In one embodiment of the present invention, para-toluene sulfonic acid is also used in pre-treatment together with melamine formaldehyde, optionally in an amount of 0.1 to 5% w/v (e.g. 1% w/v).

### Digitally Printable Formulations

The hydrophobic surface coating ink formulation is a digitally printable formulation that enables one or more layers of hydrophobic material to be applied to a surface of the substrate.

In an embodiment, the hydrophobic surface coating formulation comprises particles of a hydrophobic polymer dispersed in an aqueous vehicle.

Suitably, the concentration of particles of hydrophobic polymeric material in the aqueous vehicle is within the range of 0.5-10 wt. %.

The particles of hydrophobic polymeric material present in the formulation have an average size of less than 450 nm. Suitably, the particles of hydrophobic polymeric material present in the formulation have an average particle size of between 20 nm and 200 nm. More suitably, the particles of hydrophobic polymeric material have an average size of between 20 nm and 150 nm. More suitably, the particles of hydrophobic polymeric material have an average size of between 40 nm and 100 nm.

Following the application of the hydrophobic surface coating in step (ii), and prior to step (iii) of the process, it might be necessary or desirable to dry and/or cure the hydrophobic coating layer by heating, optionally to a temperature within the range of 50 to 300° C.

The electrically conductive track or film is formed by digitally printing an ink formulation comprising graphene and/or graphene oxide onto the surface of the substrate that has been coated with the hydrophobic surface coating.

The graphene or graphene oxide is typically present in the form of flakes that are dispersed in an aqueous medium. In the case of graphene, a suitable stabiliser, such as pyrene, may be required in order to maintain the dispersibility of the flakes in the aqueous vehicle.

Typically the graphene or graphene oxide flakes comprise up to 10 layers and the length and width of each layer is within the range of 10 nm to 2 microns.

In another embodiment, the electrically conductive formulation comprises a plurality of flakes of pristine graphene and/or graphene oxide and, optionally, particles of additional conductive agents in an aqueous vehicle.

Suitably, the concentration of graphene and/or graphene oxide in the aqueous vehicle is within the range of 0.01 to 10 mg/ml. More suitably, the concentration of pristine graphene and/or graphene oxide in the aqueous vehicle may be within the range of 0.01 to 5 mg/ml.

In order to be suitable for digital (e.g. inkjet) printing, the ink formulations used herein need to have a certain surface tension and viscosity.

Suitably, the hydrophobic surface coating ink formulation and the electrically conductive ink formulation have a surface tension within the range 10 to 72 mN/m. More suitably, the ink formulations used herein have a surface tension within the range 20 to 60 mN/m. Even more suitably, the ink formulations used herein have a surface tension within the range 28 to 45 mN/m. In an embodiment, the ink formulations used herein have a surface tension within the range 28 to 35 mN/m.

The hydrophobic surface coating ink formulation and the electrically conductive ink formulation used herein also suitably have a viscosity within the range of 2 to 300 cPs. More suitably, the ink formulations used herein have a viscosity within the range of 2 to 200 cPs. Even more suitably, the ink formulations used herein have a viscosity within the range of 2-30 cPS. Yet even more suitably, the ink formulations used herein have a viscosity within the range of 2-20 cPS. Most suitably, the ink formulations used herein have a viscosity within the range of 2-15 cPS.

Suitably, the hydrophobic coating ink formulation and/or the electrically conductive ink formulation used herein comprise one or more surface tension modifiers and/or one or more viscosity modifiers.

Any suitable surface tension modifier may be used in the ink formulations. The surface tension modifier is suitably a water soluble surface active material. Examples of suitable materials include surfactants. Non-ionic surfactants are generally preferred. Any suitable non-ionic surfactant may be used. Typical examples include Triton, Tween, poloxamers, cetomacrogol 1000, cetostearyl alcohol, cetyl alcohol, cocamide DEA, monolaurin, nonidet P-40, nonoxynols, decyl glucoside, pentaethylene glycol monododecyl ether, lauryl glucoside, ( )eyl alcohol, and polysorbate.

In a particular embodiment, the surface tension modifier is Triton.

The amount of surface tension modifier present in the ink formulation is an amount sufficient to provide the desired surface tension (i.e. a surface tension of 10 to 72 mN/m, or more preferably 20 to 60 mN/m, or even more preferably 28 to 45 mN/m).

Typically, the surface tension modifier is present in the formulations of the present invention at an amount of from 0.01 to 0.5 g/dL. Suitably, the surface tension modifier is present in the formulations of the present invention at an amount of 0.04 to 0.2 g/dL. In an embodiment, the surface tension modifier is present in the formulations of the present invention at an amount of 0.04 to 0.1 g/dL.

Any suitable viscosity modifier may be used in the formulations of the present invention. The viscosity modifier is suitably a water miscible co-solvent. Examples of suitable viscosity modifiers include (and are not limited to) glycols (e.g. ethylene glycol, propylene glycol), ethers (e.g.ethylene glycol methyl ether), alcohols (e.g. 1-propanol, 2-butanol or glycerol), esters (ethyl lactate), ketones (e.g. methyl ethyl ketone (MEK)) and organo-sulphur compounds (e.g. sulfolane).

In a particular embodiment, the viscosity modifier is selected from ethylene glycol, propylene glycol, ethylene glycol methyl ether, or an alcohol (e.g. glycerol or 2-butanol).

The amount of viscosity modifier present in the ink formulation is suitably sufficient to provide the final formulation with the desired viscosity (e.g. a viscosity of 2 to 300 cPs, 2 to 30 cPs, or more preferably 2 to 20 cPs).

Typically, the viscosity modifier is present in the formulations of the present invention at an amount of from 0.01 to 60 wt. %. Suitably, the viscosity modifier is present in the formulations of the present invention at an amount of from 0.03 to 50 wt. %. In an embodiment, the viscosity modifier is present in the formulations of the present invention at an amount of from 0.03 to 10 wt. %.

Suitably, the hydrophobic coating ink formulations and/or the electrically conductive ink formulations of the present invention do not evaporate readily, i.e. they are substantially non-volatile at normal inkjet printing temperatures (e.g. at a standard room temperature of 20 to 25° C.). This prevents the clogging of the printer nozzle.

Suitably, the ink formulations are water based, i.e. the hydrophobic coating ink formulations and/or the electrically conductive ink formulations comprise an aqueous vehicle.

The ‘aqueous vehicle’ may also comprise other solvents. It may therefore comprise organic solvents which may or may not be miscible with water. Where the aqueous medium comprises organic solvents, those solvents may be immiscible or sparingly miscible and the aqueous medium may be an emulsion. The aqueous medium may comprise solvents which are miscible with water, for example alcohols (e.g. methanol and ethanol). The aqueous medium may comprise one or more additives which may be ionic, organic or amphiphilic. Examples of possible additives include surfactants, viscosity modifiers, pH modifiers, and dispersants.

Furthermore, the aqueous vehicle may additionally have other particulate components dispersed within it, such as, for example, metallic particles (e.g. silver particles) and/or carbon nanotubes.

### Applications

The present invention further relates to electronic circuits and devices that comprise the electrically conductive materials of the present invention.

In a particular embodiment of the invention, the porous substrate is a textile material, which is provided with a hydrophobic surface coating and an electrically conductive track or film printed onto the hydrophobic surface coating material. Electrically conductive textiles are therefore a particularly useful application for this technology. The electrically conductive films or tracks can be readily printed onto textile garments by the procedures described herein.

Thus, in one aspect, the present invention comprises an electronic circuit comprising an electronically conductive material, as defined herein.

In another aspect, the present invention comprises an electronic device comprising an electronic circuit, as defined herein.

In yet another aspect, the present invention comprises a textile garment comprising an electronically conductive material, as defined herein.

Suitable textile garments include any item of clothing comprising, consisting essentially of, or consisting of any suitable textile described herein. Non-limiting examples of suitable textile garments include t-shirts, jumpers, trousers, scarfs, gloves, hats and vests.

Examples of suitable electronic devices that may comprise an electrically conductive material of the present invention include antenna elements (such as RFID devices), sensors, power generators, light emitting diodes, photovoltaic cells.

### EXAMPLES

Embodiments of the invention will be described, by way of example only, with reference to the accompanying drawings, in which:

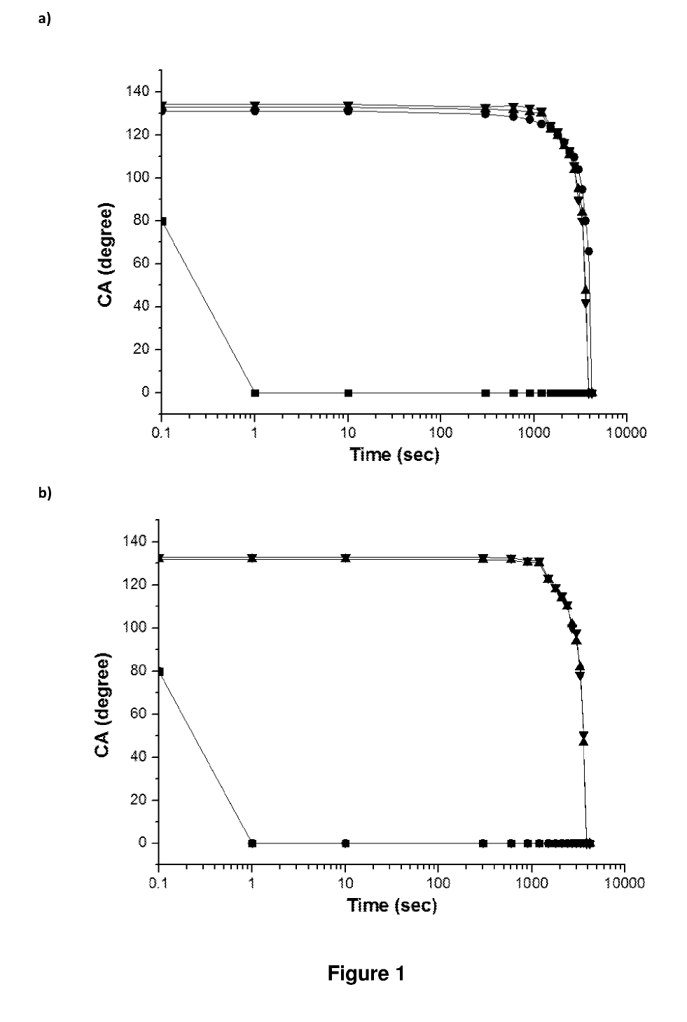

FIG. 1 shows the contact angle of distilled water versus time at 25° C. on inkjet printed cotton fabrics (BD022) with polystyrene nanoparticles: (a) before wash and (b) after wash, wherein: (▪) control fabric; (●) NP1 without MF pre-treatment; (▴) NP1 with MF pre-treatment; and (▾) NP5 with MF pre-treatment.

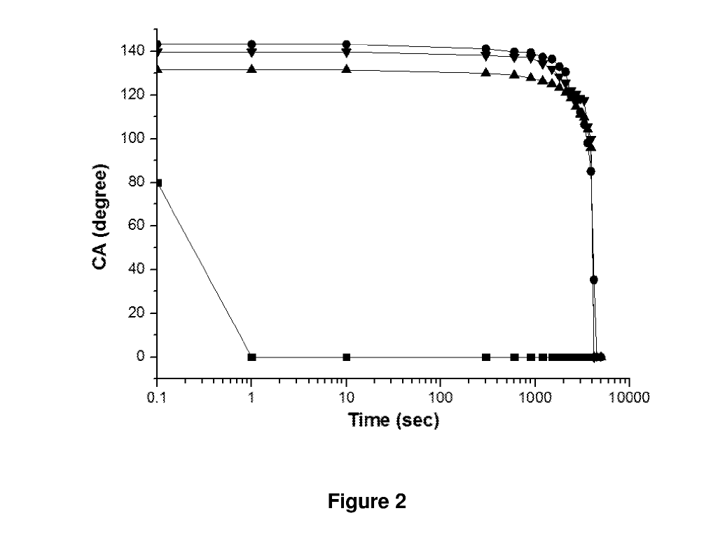

FIG. 2 shows the contact angle of distilled water versus time at 25° C. on inkjet printed polyester fabrics (MK14) with nanoparticles before wash.

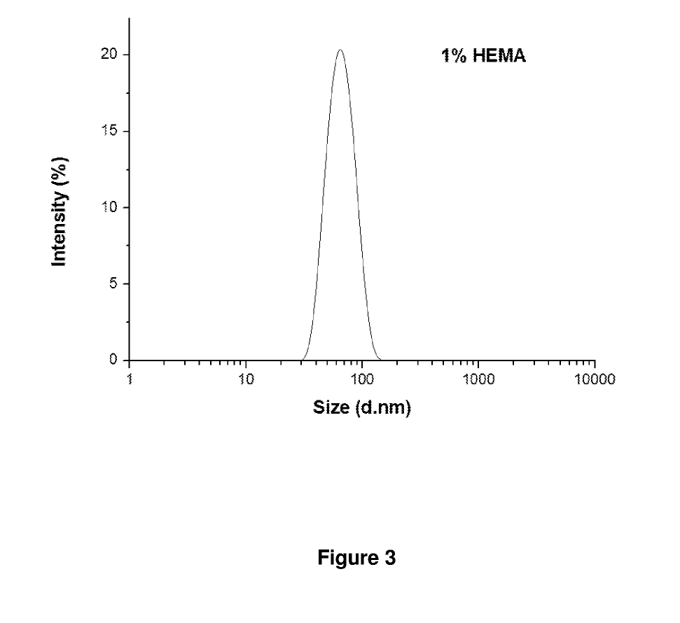

FIG. 3 shows the particle size distribution of cross-linked polystyrene nanoparticles (NP1). The Z-Average particle size of the polystyrene nanoparticle was found to be 63.12 nm (PDI=0.055)

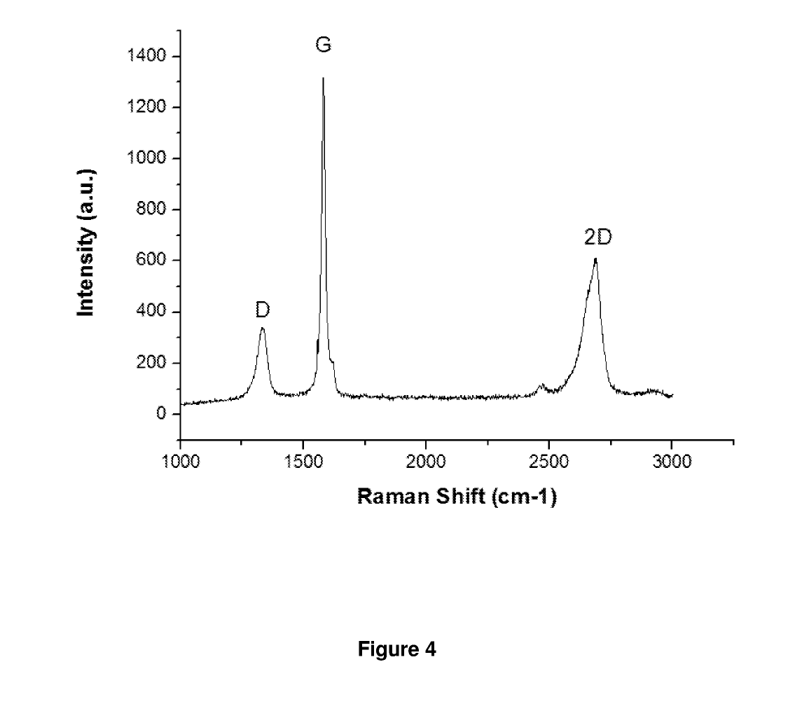

FIG. 4 shows the Raman spectra of a BS8 pristine graphene dispersion drop casted onto a Si+SiO₂wafer.

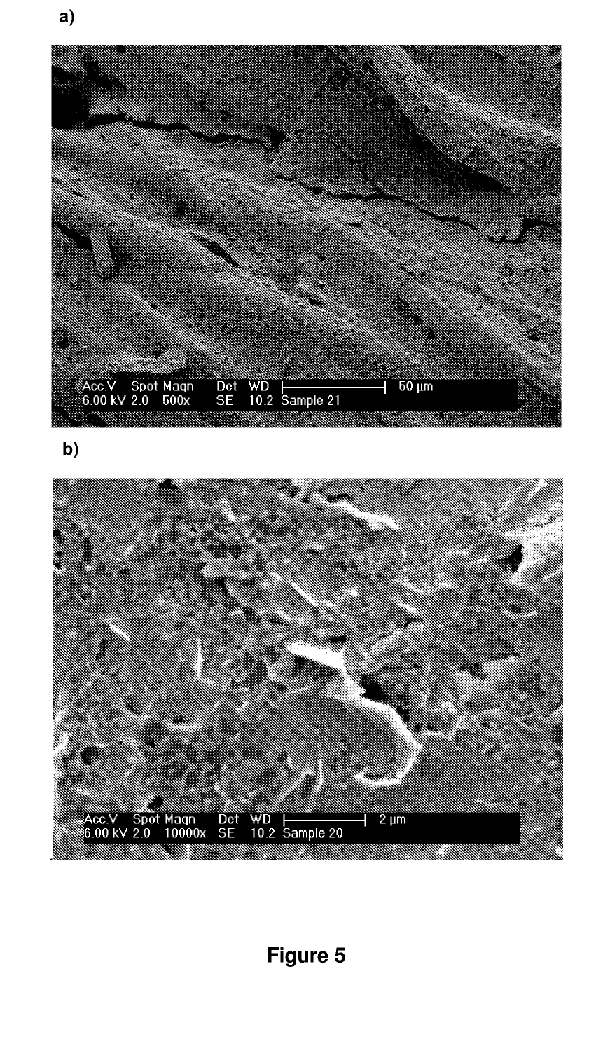

FIG. 5 shows the SEM images for 6 layers of inkjet printed composite ink (ink C) onto 12 layers of the polystyrene hydrophobic coating (NP1) printed on MF pre-treated 100% cotton fabric, at both a) 500× optical zoom and b) 10000× optical zoom.

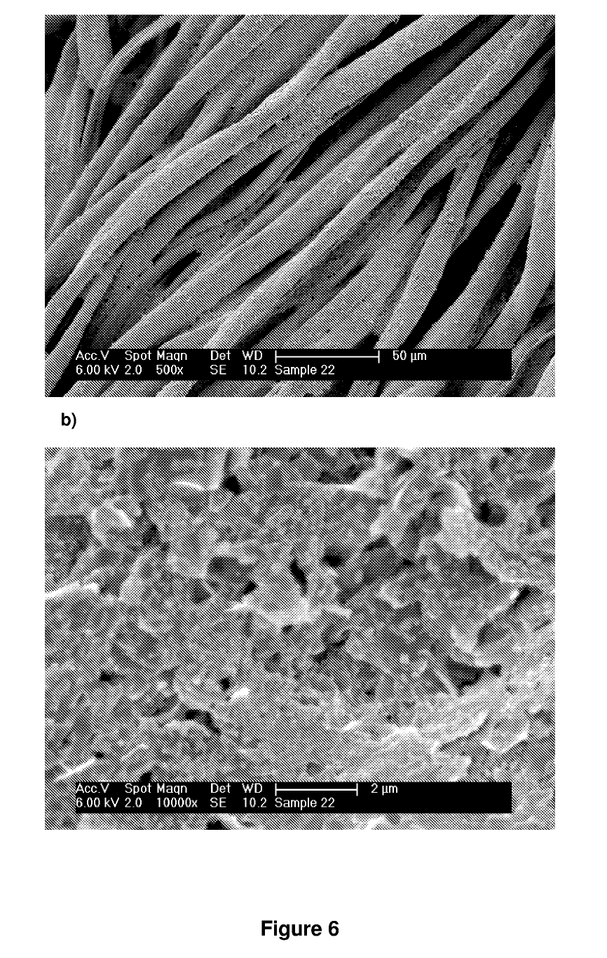

FIG. 6 shows SEM images for 6 layers of inkjet printed composite ink (ink C) onto 12 layers of the polystyrene hydrophobic coating (NP1) printed on untreated 100% cotton fabric, at both a) 500× optical zoom and b) 10000× optical zoom.

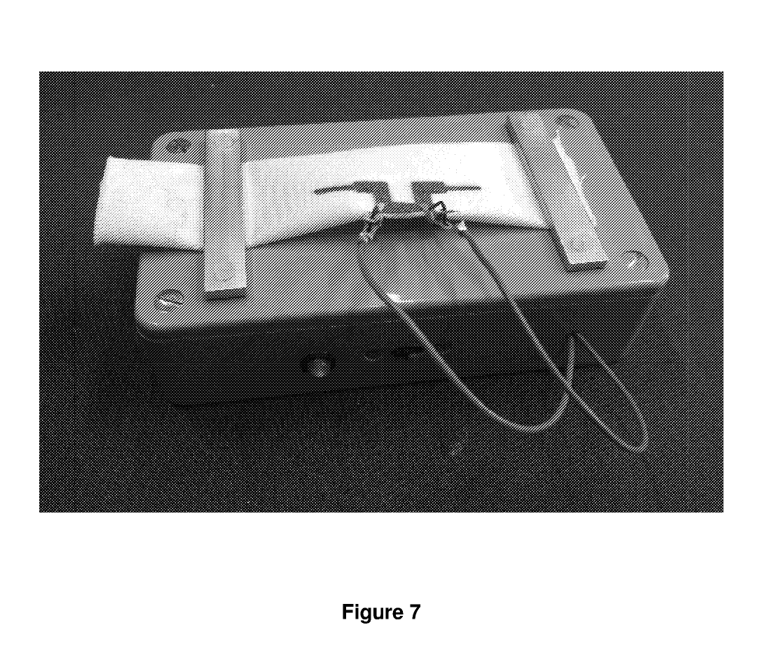

FIG. 7 shows a LED light connected to an electrically conductive textile material of the present invention and a suitable power supply.

### MATERIALS

Styrene (St), divinylbenzene (DVB), hydroxyethyl methacrylate (HEMA), sodium dodecyl sulphate (SDS), ammonium persulfate (APS), glycerol, melamine formaldehyde (MF), para toluene sulfonic acid (PTSA), silver nanoparticle inks (30-35 wt. %) and Triton X-100 were purchased from Sigma-Aldrich, UK and used as received. Protective Chemical FC-3548 and Aerosil R202 fumed silica were supplied by 3M and Evonik Industries, respectively. BD022 (100% Cotton), MK14 (100% Polyester) and KG308 (35% Cotton, 65% Polyester) fabrics were provided by Royal TenCate, Netherlands.

Highly concentrated water-based graphene dispersion (BS8, 8 wt.-%) was supplied by BGT Materials Limited, UK. Silver nanoparticle inks (SA-Ag, 30-35 wt.-%), Triethylene glycol monomethyl ether (TEGMME), Polyvinylpyrrolidone (PVP) of 10 K molecular weight and Triton X-100 were purchased from Sigma-Aldrich. Nano 60 PEL paper was purchased from Printed Electronics Limited, UK. 100% Cotton fabrics (BD022) were supplied by Royal TenCate, Netherlands.

### Characterisation

The Raman spectra were obtained from a low power (<1 mVV) He—Ne laser (1.96 eV, 633 nm) in Renishaw 2000 spectrometer. The viscosity of formulated inks was measured using a Brookfield DV-II+PRO programmable digital viscometer at 25° C. temperature and surface tension was measured by using a torsion balance (model OS) for surface and interfacial tension measurement. Thermogravimetric Analysis (TGA) was conducted to investigate the thermal stability of formulated inks using a TGA Q500 (TA Instruments, USA). A Philips XL 30 Field Emission Gun Scanning Electron Microscope (SEM) was used to analyse the surface topography. Printed samples were gold-palladium (Au—Pd) coated for 90 seconds and assessed under FEG SEM with the following operating parameters: 6.0 KV, spot size 2.0, 10 mm WD and magnification: ×500 to ×40000. A Jandel four-point probe system (Jandel Engineering Ltd, Leighton, UK) was employed to measure the sheet resistance of the conductive patterns. The sheet resistance was calculated from the average of six measurements and multiplied by a correction factor of 4.5324.

The particle size of the nanoparticle dispersion was measured using Dynamic Light Scattering (DLS) techniques (Nano Z-Series, Malvern Instruments).

The hydrophobicity was assessed by measuring the contact angle (CA) of a distilled water droplet on the treated substrate, and the change of WCA with time was also measured using a Kruss Dynamic Shape Analyser DSA 100. The WCA readings were taken at every ˜5 min and the respective graphs were plotted.

### Hydrophobic Surface Coating

Synthesis of Polystyrene Based Nanoparticles

Hydroxyl functionalised cross-linked styrene/divinylbenzene nanoparticles were synthesised using conventional emulsion polymerisation containing either 1 wt.-% (NP1) or 5 wt.-% HEMA (NP5) on total monomer. 250 ml of deionised water and 20 ml of a 3.38 mmol, solution of SDS were added to 500 ml flange flask fitted with a condenser, nitrogen flow, a 5 blade impeller mechanical stirrer and a thermometer; stirred for 15 min at 600 rpm under nitrogen flow. St (21 g, 216 mmol), DVB (2.1 g, 16.1 mmol) and HEMA were then added and stirred at 600 rpm whilst being degassed for 1 hour and heated to 80° C. APS (1 g, 11.6 mmol), dissolved in 10 ml of deionised water and degassed for 30 min in a vial, added to the reaction flask. The reaction was run for 24 hr; stopped and run another 2 hr for cooling. The resultant suspension was passed through 50 μm nylon gauze to remove any coagulant; and nanoparticles were used without any further treatment.

### Surface Pre-Treatment and Inkjet Printing

A 5:1 mixture of 50% w/v MF in methanol and 1% w/v PTSA in methanol was deposited onto textiles using a Kruss DSA100 (NE43 needle, Ø0.7 mm) and dried at 130° C. for 30 min. Candidate inkjet inks were formulated using glycerol or 2-butanol and Triton X-100 to increase the viscosity and reduce the surface tension of the dispersions, respectively. Inks were filtered through a 0.45 μm filter to remove any impurities and large particles that could block the nozzles.

A Dimatix DMP-2800 inkjet printer (Fujifilm Dimatix Inc., Santa Clara, USA) was used in this study, equipped with a disposable piezo “inkjet” cartridge. This printer can create and define patterns over an area of about 200×300 mm and handle substrates up to 25 mm thick, being adjustable in the Z direction. The nozzle plate consists of a single row of 16 nozzles of 21.5 μm diameter spaced 254 μm with typical drop diameter of 27 μm and 10 pl drop size. Print head height was adjusted to 0.75 mm; formulated inks were jetted reliably and reproducibly at 24 V and ambient temperature. It was important however to use the primed-head within 48 hours to avoid non recoverable nozzle dry out. In order to compare the hydrophobicity achieved using both the conventional padding method and the digital inkjet printing method, the fabrics supplied were also padded into an acidic solution containing 40 g/L Protective Chemical FC-3548; dried at 100° C. for 5 min and thermally fixed by curing at 180° C. for 1 min.

The inkjet printing of nanoparticles onto a range of textile materials such as cotton, polyester and their blends significantly improved water repellent properties, achieving a higher WCA up to 160° as illustrated in FIGS. 1a and 1b.

During contact angle measurement, the water droplets falling onto untreated cotton fabrics were absorbed almost immediately after hitting the surface, FIG. 1a, as the cotton fibres provide higher polarity, hydrogen-bonding and wettability in their natural form.

The inkjet printing of a few layers of polystyrene nanoparticles onto cotton fabric introduced surface hydrophobicity and imparted measureable WCA onto printed pattern.

The WCAs for NP1 printed on 100% cotton fabrics were found to be 131.2° and 132.9° for the fabrics without and with MF pre-treatment, respectively (FIG. 1a).

The WCAs for NP1 printed on polyester fabric, without any MF treatment, imparted a relatively high WCA of 143.3° (FIG. 2).

### Electrically Conductive Formulations

### Synthesis and Characterisation

In order to find the optimum percolation threshold for diluted SA-Ag ink, a series of composite inks were formulated by blending BS8, TEGMME and 1% PVP (in TEGMME) with SA-Ag inks. The formulated composite inks were deposited onto PEL paper using a triple reservoir cube film applicator (TQC, Netherland) and cured at 150° C. for 1 hr to form 90 μm thick conductive films.

TABLE 1
The composition of electrically conductive composite inks

| | % Materials (as supplied) | | |
|---|---|---|---|
| | | | 1% PVP |
| | BS8 | SA-Ag | (TEGMME) |
| Ink A | 40 | 60 | 0 |
| Ink B | 35 | 60 | 5 |
| Ink C | 30 | 60 | 10 |
| Ink D | 25 | 60 | 15 |
| Ink E | 20 | 60 | 20 |

The formulated inks were printed using a Dimatix DMP-2800 inkjet printer (Fujifilm Dimatix Inc., Santa Clara, USA) which can create and define patterns over an area of 200×300 mm and handle substrates up to 25 mm thick, being adjustable in the Z direction. This printer is equipped with a disposable piezo inkjet cartridge and the nozzle plate consists of a single row of 16 nozzles of 21.5 μm diameter spaced 254 μm with typical drop diameter 27 μm and 10 pl drop size. Print head height was adjusted to 0.75 mm and the formulated inks were jetted at 37° C. temperature, using frequent cleaning cycles during the printing. A few layers (1-5 layers) of composite inks were printed to produce a conductive pattern of 1 cm² area and thermally-cured at 150° C. for 1 hr in an oven to sinter the conductive inks.

In order to demonstrate the potential electronic textiles applications of graphene-based composite inks, a hydrophobic coating was inkjet printed onto 100% cotton plain twill fabrics (B022) by depositing 12 layers of nanoparticles (NP1) as detailed above. Subsequently, six layers (6 L) of graphene inks (formulated from BS8 dispersion) or composite inks C were inkjet printed onto hydrophobic areas of cotton fabrics.

The viscosity and surface tension of the BS8 pristine graphene dispersion was found to be 1.32 cP and 71 mN/m, respectively.

The BS8 pristine graphene dispersion was supplied by BGT Materials Limited and was found to have an average flake size of approximately 1 μm.

The Raman spectra of BS8 shows a very well-defined 2D band at 2686.36 cm⁻¹, a G band at 1579.98 cm⁻¹ and a D band at 1334.6 cm⁻¹ (FIG. 4). The G-peak indicates a graphite carbon structure, whereas the D peak, only observed at the sample edge, indicates defects typically attributed to the structural edge effects such as epoxides covalently bonded to the basal plane of graphene [10, 11]. It is possible to identify the number of graphene layers from the shape of the 2D peak [12], which is very sharp for monolayer graphene. It can therefore be implied that BS8 graphene dispersion contains multi-layer graphene sheets.

### Electronic Textile Application

Table 3 shows the sheet resistances of conductive patterns printed on untreated and 12 layer NP1 inkjet printed hydrophobic textiles using graphene ink and Composite ink C. The sheet resistance of NP1 printed textiles with BS8 ink was found to be 161.55 Ω/sq. and that for untreated cotton was 2238.45 Ω/sq; which were significantly reduced to 2.11 Ω/sq. and 30.89 Ω/sq. for composite Ink C, Table 3. FIGS. 5 and 6 show the SEM images of inkjet printed conductive textiles with composite Ink C. The inkjet printing of hydrophobic NP1 onto cotton fabrics provided inter-fibre bonding, FIGS. 5a and 5b, which helped to produce a continuous film of Ag NPs and imparted very good inter-connections between graphene sheets. Therefore, the sheet resistances of the conductive patterns onto NP1 printed cotton were found to be much lower than that of untreated textiles.

TABLE 3
Sheet resistances of inkjet printed conductive patterns with
composite Ink C and graphene inks onto 100% cotton fabrics

| | Sheet |
|---|---|
| | Resistance |
| Inkjet Inks and Substrates | (Ω/sq.) |
| 6L BS8 inks printed onto NP1 (12L) printed | 161.55 |
| 100% Cotton | |
| 6L BS8 inks printed onto untreated 100% Cotton | 2238.45 |
| 6L Composite Ink C printed onto NP1 (12L) | 2.11 |
| printed 100% Cotton | |
| 6L Composite Ink C printed onto untreated | 30.89 |
| 100% Cotton | |

In order to demonstrate a potential application, an LED light was illuminated by connecting it with a power supply and conductive textiles as shown in FIG. 7.

While specific embodiments of the invention have been described herein for the purpose of reference and illustration, various modifications will be apparent to a person skilled in the art without departing from the scope of the invention as defined by the appended claims.

### REFERENCES

1. Kim, D. H., N. Lu, R. Ma, Y. S. Kim, R. H. Kim, S. Wang, J. Wu, S. M. Won, H. Tao, A. Islam, K. J. Yu, T. i. Kim, R. Chowdhury, M. Ying, L. Xu, M. Li, H. J. Chung, H. Keum, M. McCormick, P. Liu, Y. W. Zhang, F. G. Omenetto, Y. Huang, T. Coleman, and J. A. Rogers, Epidermal electronics. Science, 2011, 333(6044): p. 838-843.
2. Gaikwad, A. M., G. L. Whiting, D. A. Steingart, and A. C. Arias, Highly flexible, printed alkaline batteries based on mesh-embedded electrodes. Advanced Materials, 2011, 23(29): p. 3251-3255.
3. Minhun, J., K. Jaeyoung, N. Jinsoo, L. Namsoo, L. Chaemin, L. Gwangyong, K. Junseok, K. Hwiwon, J. Kyunghwan, A. D. Leonard, J. M. Tour, and C. Gyoujin, All-printed and roll-to-roll-printable 13.56-MHz-operated 1-bit RF tag on plastic foils. Electron Devices, IEEE Transactions on, 2010, 57(3): p. 571-580.
4. Zhou, L., A. Wanga, S. C. Wu, J. Sun, S. Park, and T. N. Jackson, All-organic active matrix flexible display. Applied Physics Letters, 2006, 88(8): p. 083502.
5. Gelinck, G. H., H. E. A. Huitema, E. van Veenendaal, E. Cantatore, L. Schrijnemakers, J. B. P. H. van der Putten, T. C. T. Geuns, M. Beenhakkers, J. B. Giesbers, B.-H. Huisman, E. J. Meijer, E. M. Benito, F. J. Touwslager, A. W. Marsman, B. J. E. van Rens, and D. M. de Leeuw, Flexible active-matrix displays and shift registers based on solution-processed organic transistors. Nature Materials, 2004, 3(2): p. 106-110.
6. Sekitani, T., T. Yokota, U. Zschieschang, H. Klauk, S. Bauer, K. Takeuchi, M. Takamiya, T. Sakurai, and T. Someya, Organic nonvolatile memory transistors for flexible sensor arrays. Science, 2009, 326(5959): p. 1516-1519.
7. Myny, K., S. Steudel, P. Vicca, M. J. Beenhakkers, N. A. J. M. van Aerle, G. H. Gelinck, J. Genoe, W. Dehaene, and P. Heremans, Plastic circuits and tags for 13.56 MHz radio-frequency communication. Solid-State Electronics, 2009, 53(12): p. 1220-1226.
8. Han, T. H., Y. Lee, M. R. Choi, S. H. Woo, S. H. Bae, B. H. Hong, J. H. Ahn, and T. W. Lee, Extremely efficient flexible organic light-emitting diodes with modified graphene anode. Nature Photonics, 2012, 6(2): p. 105-110.
9. Park, S. and S. Jayaraman, Smart textiles: Wearable electronic systems. MRS Bulletin, 2003, 28(08): p. 585-591.
10. Ferrari, A. C., J. C. Meyer, V. Scardaci, C. Casiraghi, M. Lazzeri, F. Mauri, S. Piscanec, D. Jiang, K. S. Novoselov, S. Roth, and A. K. Geim, Raman spectrum of graphene and graphene layers. Physical Review Letters, 2006, 97(18): p. 187401.
11. Shin, K. Y., J. Y. Hong, and J. Jang, Micropatterning of graphene sheets by inkjet printing and its wideband dipole-antenna application. Advanced Materials, 2011, 23(18): p. 2113-2118.
12. Hernandez, Y., V. Nicolosi, M. Lotya, F. M. Blighe, Z. Sun, S. De, I. T. McGovern, B. Holland, M. Byrne, Y. K. Gun'Ko, J. J. Boland, P. Niraj, G. Duesberg, S. Krishnamurthy, R. Goodhue, J. Hutchison, V. Scardaci, A. C. Ferrari, and J. N. Coleman, High-yield production of graphene by liquid-phase exfoliation of graphite. Nature Nanotechnology, 2008, 3(9): p. 563-568.

1. An electrically conductive material comprising:
a porous substrate material;
a hydrophobic surface coating covering at least a portion of a surface of the porous substrate material;
and an electrically conductive track or film disposed on the hydrophobic surface coating;
wherein:
(i) the hydrophobic coating forms a hydrophobic surface on the porous substrate material having an equilibrium contact angle of water against air, at 25° C., of greater than or equal to 60° and less than or equal to 175°; and
(ii) the electrically conductive track or film comprises graphene and/or reduced graphene oxide.

2. An electrically conductive material according to claim 1, wherein the porous substrate material is selected from a textile or cellulosic material (e.g. paper).

3. An electrically conductive material according to claim 1, wherein the porous substrate material is a textile (e.g. cotton).

4. An electrically conductive material according to claim 1, wherein the hydrophobic coating covering at least a portion of a surface of the porous substrate material is a hydrophobic material selected from the group consisting of styrene, (meth)acrylate, acrylate, ester, olefin, vinyl ester, vinyl pyrrolidone and vinylpyridine based polymers.

5. An electrically conductive material according to claim 1, wherein the hydrophobic coating comprises particles formed from a hydrophobic polymeric material.

6. An electrically conductive material according to claim 5, wherein the hydrophobic coating comprises particles formed from co-polymers comprising styrene, divinylbenzene and hydroxyl methacrylate.

7. An electrically conductive material according to claim 1, wherein the hydrophobic coating forms a hydrophobic surface on the porous substrate material having an equilibrium contact angle of water against air, at 25° C., of greater than or equal to 90° and less than or equal to 165°.

8. An electrically conductive material according to claim 1, wherein the hydrophobic coating forms a hydrophobic surface on the porous substrate material having an equilibrium contact angle of water against air, at 25° C., of greater than or equal to 90° and less than or equal to 145°.

9. An electrically conductive material according to claim 1, wherein the hydrophobic coating forms a hydrophobic surface on the porous substrate material having an equilibrium contact angle of water against air, at 25° C., of greater than or equal to 90° and less than or equal to 135°.

10. An electrically conductive material according to claim 1, wherein the hydrophobic coating forms a hydrophobic surface on the porous substrate material having an equilibrium contact angle of water against air, at 25° C., of greater than or equal to 100° and less than or equal to 125°.

11. An electrically conductive material according to claim 1, wherein the electrically conductive track or film comprises:
(i) graphene;
(ii) reduced graphene oxide; or
(iii) graphene or reduced graphene oxide in combination with one or more additional conductive agents.

12. An electrically conductive material according to claim 11, wherein the additional conductive agent is selected from a silver precursor, silver nanoparticles, carbon nanotubes, or poly(3,4-ethylenedioxythiophene) polystyrene sulfonate (PEDOT/PSS).

13. A process for forming an electrically conductive material according to claim 1, wherein the process comprises:
(i) providing a porous substrate material;
(ii) digitally printing a hydrophobic surface coating ink formulation onto at least a portion of a surface of the porous substrate material to form a hydrophobic surface on the substrate having an equilibrium contact angle of water against air, at 25° C., of greater than or equal to 60° and less than or equal to 175°;
(iii) digitally printing or digitally applying an electrically conductive ink formulation comprising graphene and/or graphene oxide onto the hydrophobic surface of the substrate to form a film or track and thereafter reducing any graphene oxide present to form a track or film comprising reduced graphene oxide; and
(iv) optionally, and if necessary, heating the printed electronically conductive formulation to between 50° C. and 300° C. so as to cure the electronically conductive formulation.

14. A process according to claim 13, wherein the digital printing in steps (ii) and (iii) is inkjet printing.

15. A process according to claim 13, wherein the porous substrate material is selected from a textile or cellulosic material (e.g. paper).

16. A process according to claim 13, wherein the porous substrate material is a textile (e.g. cotton).

17. A process according to claim 13, wherein the hydrophobic coating forms a hydrophobic surface on the substrate material having an equilibrium contact angle of water against air, at 25° C., of greater than or equal to 80° and less than or equal to 120°.

18. A process according to claim 13, wherein the hydrophobic coating ink formulation comprises particles of a hydrophobic polymeric material in an aqueous vehicle.

19. A process according to claim 18, wherein the concentration of particles of hydrophobic polymeric material in the aqueous vehicle is within the range of 0.5-10 wt-%.

20. A process according to claim 13, wherein the hydrophobic coating ink formulation has a viscosity within the range of 2 to 300 cPs at 25° C.

21. A process according to claim 13, wherein the hydrophobic coating ink formulation has a viscosity within the range of 2 to 30 cPs at 25° C.

22. A process according to claim 13, wherein the hydrophobic coating ink formulation has surface tension within the range of 10 to 72 mN/m.

23. A process according to claim 13, wherein the electrically conductive ink formulation comprises a plurality of flakes of pristine graphene and/or graphene oxide and, optionally, particles of additional conductive agents in an aqueous vehicle.

24. A process according to claim 23, wherein the concentration of flakes of pristine graphene and/or graphene oxide in the aqueous vehicle is within the range of 0.01 to 10 mg/ml.

25. A process according to claim 13, wherein the electrically conductive ink formulation has a viscosity within the range of 2 to 30 cPs at 25° C.

26. A process according to claim 13, wherein the electrically conductive ink formulation has a surface tension within the range of 10 to 72 mN/m.

27. An electronic circuit comprising an electronically conductive material according to claim 1.

28. An electronic device comprising an electronic circuit according to claim 27.

29. A textile garment comprising an electronically conductive material according to claim 1.
